(19) United States
(12) Patent Application Publication
(10) Pub. No.: US 2024/0258034 A1
(43) Pub. Date: Aug. 1, 2024

(54) HIGH PERFORMANCE CAPACITORS AND CURRENT PATH ARRANGEMENTS

(71) Applicant: Resonant Link, Inc., South Burlington, VT (US)

(72) Inventors: Aaron Stein, Essex, VT (US); Phyo Aung Kyaw, Winooski, VT (US); Charles R. Sullivan, West Lebanon, NH (US); Milovan Kovacevic, Palo Alto, CA (US); Carroline Collopy, Feasterville-Trevose, TN (US)

(73) Assignee: Resonant Link, Inc., South Burlington, VT (US)

(21) Appl. No.: 18/633,862

(22) Filed: Apr. 12, 2024

Related U.S. Application Data
(63) Continuation of application No. PCT/US22/47675, filed on Oct. 25, 2022.
(60) Provisional application No. 63/271,399, filed on Oct. 25, 2021.

(51) Int. Cl. H01G 4/228; H01G 4/40; H02J 50/10; H05K 1/02

(52) U.S. Cl. CPC H01G 4/228; H01G 4/40; H02J 50/10; H05K 1/0231

(57) ABSTRACT

An apparatus includes at least one conductive sheet forming a forward current path from a first terminal of the at least one conductive sheet to a second terminal of the at least one conductive sheet. The at least one conductive sheet has a top, a bottom, and at least one edge. The apparatus also includes at least one conductor forming a return current path from the second terminal. The at least one conductor extends over the top of the at least one conductive sheet or below the bottom of the at least one conductive sheet.

### RELATED APPLICATIONS

This application is a Continuation of International Patent Application Serial No. PCT/US2022/047675, filed Oct. 25, 2022, titled “HIGH PERFORMANCE CAPACITORS AND CURRENT PATH ARRANGEMENTS”, which claims the benefit of U.S. Provisional Application Ser. No. 63/271,399, filed Oct. 25, 2021, titled “HIGH PERFORMANCE CAPACITORS,” each of which is incorporated herein by reference in its entirety.

### BACKGROUND

### 1. Technical Field

The apparatus and techniques described herein relate to reduction of proximity effect losses in conductors, such as electrodes of capacitors, and losses in sheet conductors due to lead placement.

### 2. Discussion of the Related Art

Capacitors are used in a variety of applications. One application of capacitors is in a matching network for a wireless power transfer coil. Capacitors may be mounted on printed circuit boards or in other locations.

In many applications, it would be advantageous to improve efficiency by minimizing power losses.

### SUMMARY

Some aspects relate to an apparatus that includes at least one conductive sheet forming a forward current path from a first terminal of the at least one conductive sheet to a second terminal of the at least one conductive sheet. The at least one conductive sheet has a top, a bottom, and at least one edge. The apparatus also includes at least one conductor forming a return current path from the second terminal. The at least one conductor extends over the top of the at least one conductive sheet or below the bottom of the at least one conductive sheet.

The apparatus may further comprise circuitry connected between the first terminal and the second terminal.

The circuitry may be connected between a first portion of the at least one conductive sheet and a second portion of the at least one conductive sheet.

The circuitry may comprise at least one capacitor.

The circuitry may comprise at least one switch.

The circuitry may comprise a rectifier or an inverter.

The apparatus may further comprise second circuitry connected between the first terminal and the second terminal.

The apparatus may comprise an insulating region at least partially separating respective current paths in the at least one conductive sheet.

The insulating region may fully insulate the respective current paths.

The second circuitry may be of a same type as the circuitry or of a different type.

The at least one conductive sheet may be formed in a conductive layer of a printed circuit board.

The at least one conductor may comprise a second conductive layer of the printed circuit board.

The at least one conductor may comprise one or more vias connecting the at least one conductive sheet and the second conductive layer.

The at least one conductor may further comprise or more second vias extending from the second conductive layer to the at least one conductive sheet.

The at least one conductor may further comprise litz wire or a foil conductor.

The at least one conductor may comprise a plurality of litz conductors connected in parallel and connected to the second terminal at different locations.

The at least one conductive sheet may be electrically connected to a coil.

The at least one conductor may form a lead of a coil.

The coil may be a wireless power transfer coil or an inductive component.

The at least one conductive sheet may be electrically connected to a second coil.

Some aspects relate to an apparatus, comprising: a magnetic core; a coil disposed within the magnetic core; and at least one capacitor disposed within the magnetic core, the at least one capacitor being coupled to the wireless power transfer coil.

The coil may be a wireless power transfer coil.

The at least one capacitor may be mounted on or over one or more conductors of the coil.

The at least one capacitor may be oriented in a circumferential direction.

The at least one capacitor may be oriented in a radial direction.

Some aspects relate to an apparatus, comprising: a plurality of conductive layers; and a magnetic core configured to straighten magnetic field lines along the plurality of conductive layers.

The plurality of conductive layers may be electrodes of one or more capacitors.

The magnetic core may extend along edges of the plurality of conductive layers at a position beyond the edges of the plurality of conductive layers.

The magnetic core may comprise one or more protrusions extending above and/or below the plurality of conductive layers.

Some aspects relate to an apparatus, comprising: a capacitor disposed on a substrate, the capacitor having a plurality of electrodes oriented vertically with respect to the substrate.

The electrodes may have a rectangular configuration or a cylindrical configuration.

Some aspects relate to an apparatus, comprising: a capacitor disposed on a substrate; and a lead extending from a top of the capacitor and to a location displaced from a body of the capacitor, and extending from the location displaced from the body of the capacitor to the substrate.

Some aspects relate to an apparatus, comprising: a first capacitor disposed on a substrate; a second capacitor disposed on the substrate; and a conductive connection between a top of the first capacitor and a top of the second capacitor, wherein the second capacitor provides a return current path for the first capacitor.

The second capacitor may comprise a plurality of capacitors located at respective positions around an exterior of the first capacitor.

Some aspects relate to a method of making or using any of the apparatus described or claimed herein.

The foregoing summary is provided by way of illustration and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques and devices described herein.

FIG. 1 shows a capacitor in which the magnetic field lines are not parallel to the electrodes of the capacitor.

FIG. 2A-2F show examples of a magnetic core straightening magnetic field lines to be approximately parallel to conductors, as well as capacitor placements and orientations.

FIG. 3 shows examples of film capacitors.

FIG. 4 illustrates a capacitor with electrodes oriented vertically with respect to an underlying substrate.

FIG. 5 shows lead(s) connecting to the top of a capacitor.

FIG. 6 shows a return current path from a top of a capacitor may be provided by at least one other capacitor.

FIG. 7 shows a plurality of capacitors in a circular geometry.

FIGS. 8A-8C illustrate proximity effect losses at the edge of a sheet conductor when a return lead is brought around the edge of the sheet conductor.

FIGS. 9A-9E show examples of configurations in which a return current path is brought over and/or under a sheet conductor, which can lower proximity effect losses.

FIGS. 10A-10E show example of configurations in which a return current path is brought over and/or under a sheet conductor with conductors such as litz wire, for example.

FIGS. 10F and 10G illustrate proximity effect losses at the edge of a sheet conductor when a return lead is brought around the edge of the sheet conductor.

FIGS. 11A-11C show examples of configurations with parallel forward current paths in different layers of a substrate.

FIGS. 12A-12C show configurations with more than one column or bank of circuitry connected in a current path between respective portions of a conductive sheet.

FIGS. 13A-13C show configurations with an insulating region partially or fully isolating current paths in a conductive sheet.

FIGS. 14A-14E show various examples of coil connections to conductors and arrangements of one or more columns or banks of circuitry and including no insulating region or full or partial insulating regions.

### DETAILED DESCRIPTION

The inventors have recognized the performance of capacitors typically degrades at high frequencies and for large capacitances. The reduction in performance is believed to be caused by the proximity effect. Obtaining a large capacitance may entail a large number of electrodes, which may cause increased losses due to the proximity effect. At high frequencies, the proximity effect losses are high.

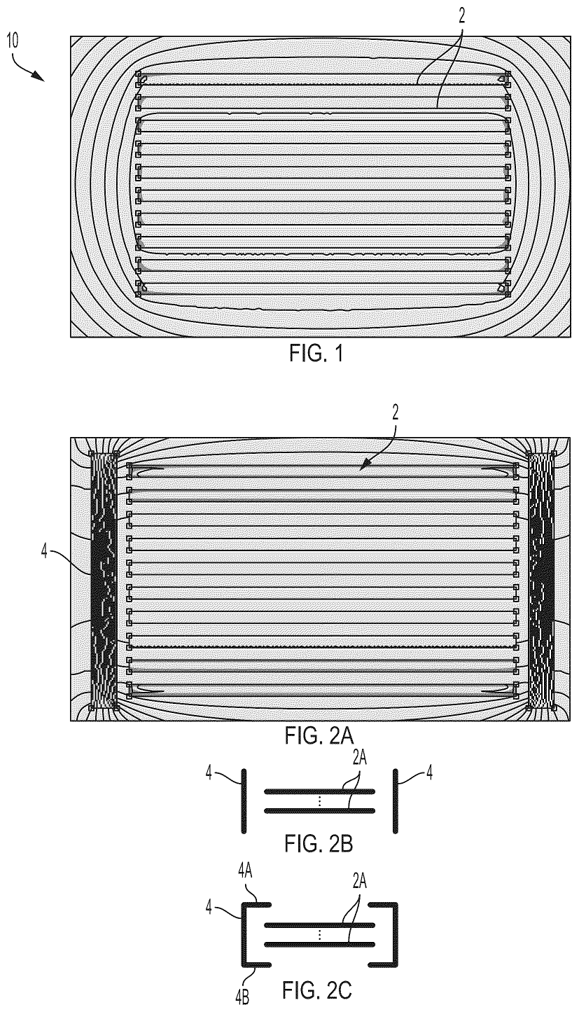

The inventors have recognized and appreciated these losses may be caused by magnetic field lines that are not parallel to the electrodes of the capacitor. A capacitor may create a magnetic field which is referred to as the self-field of the capacitor. Depending on the configuration, the magnetic field lines may not be parallel to the electrodes of the capacitor, as illustrated in FIG. 1, which shows the magnetic field lines at the edges of the capacitor 10 in particular are not parallel to the electrodes 2. A magnetic field line that is not perpendicular to the electrode creates an eddy current in the conductor, which increases loss and decreases quality factor.

Described herein are techniques and structures that can provide capacitors having high performance, regardless of capacitance value and frequency. Such techniques and structures may help to establish magnetic field lines that are parallel to, or more parallel to, the electrodes and/or terminations of the capacitor. Below are examples of such techniques and other techniques, which may be used individually or in any combination.

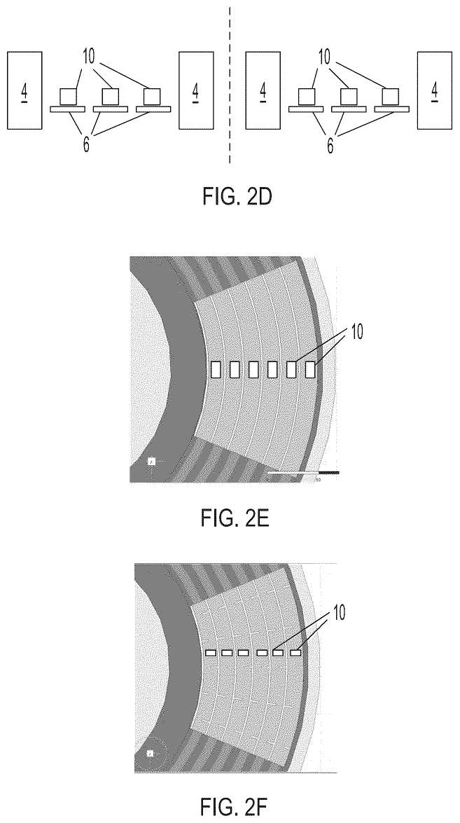

A first way of making the magnetic field lines more parallel to the electrodes is to include a magnetic core or cores along the edges of the electrodes. An example is shown below in FIG. 2A. The magnetic core 4 may make the current more uniform across each electrode, which leads to lower loss. In some embodiments, the magnetic core may extend to a position above the top of the electrodes 2 and below the electrodes 2, as shown in FIG. 2A. This technique is not limited to capacitor electrodes, and can be used for other conductors, such as foil conductors or other conductors having approximately a two-dimensional shape. FIG. 2B shows an example in which a magnetic core 4 is positioned along the edges of the conductors 2A to straighten the magnetic field lines to be approximately parallel to the conductors 2A. FIG. 2C shows an example in which the magnetic core 4 has protrusion 4A and 4B extending above and below the plurality of electrodes 2A to help straighten the magnetic field lines to be approximately parallel to the conductors 2A. In other embodiments, the protrusion(s) 4A or 4B may be omitted, and the core may include only protrusion(s) 4B below the plurality of conductors 2A or only protrusions 4A above the plurality of conductors 2A.

Another example of placing one or more such conductors within a magnetic core will be discussed following a discussion of wireless charging. Wireless charging can be used in a number of applications, such as charging of consumer electronics, medical implants, and automobile batteries, for example. To perform wireless charging, an inverter of a wireless power transmitter generates an alternating current in a wireless power transmit coil, which induces a current in a wireless power receive coil by electromagnetic induction. The term “wireless power transfer coil” refers herein to either a wireless power receive coil or a wireless power transmit coil, as well as to coils that may be controlled to perform both functions (e.g., in different modes). A wireless power receiver may have a wireless power receive coil and suitable electronics. For example, the electronics of the wireless power receiver may include a rectifier for rectifying the alternating current induced in the receive coil into direct current, and circuitry for controlling the current provided to the battery during charging. In some applications, the receive coil and associated electronics can switch into a different mode to perform the function of a wireless power transmit coil to transfer energy in the opposite direction.

In some embodiments, a coil, such as a wireless power transfer coil, may be formed within a magnetic core. Some coils may have associated capacitors, such as one or more capacitors connected in series with turns of the coil, for example. The capacitor(s) may provide the capacitance for a matching network for the wireless power transfer coil, or may serve another function, such as helping to equalize current in respective turns of a wireless power transfer coil, for example. In some embodiments, capacitors may be placed within the magnetic core so that the magnetic field lines will be approximately parallel to the electrodes of the capacitors. Such a configuration may reduce loss caused by the proximity effect. FIG. 2D shows one example of such as configuration, in which capacitors 10 may be disposed on or over the conductors 6 of the coil, between the top and bottom of the magnetic core 4. The capacitors 10 may be disposed in any suitable orientation, such as facing circumferentially, as shown in FIG. 2E, or radially, as illustrated in FIG. 2F. In the example of FIG. 2F, partial breaks in the conductors of the coil may direct the current in the conductors to flow radially back and forth in the areas of the capacitors 10.

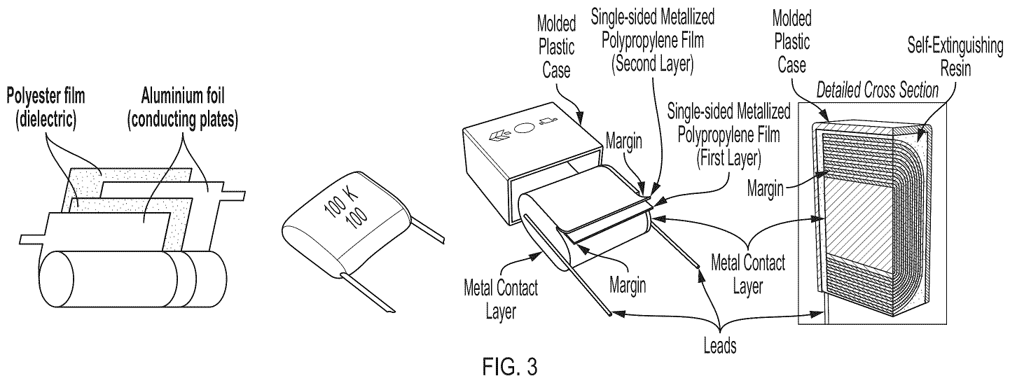

For film capacitors (e.g., having barrel-wound film and foil layers), magnetic field lines may be made parallel to or more parallel to the electrodes by positioning them vertically with respect to a substrate. Examples of film capacitors are shown in FIG. 3.

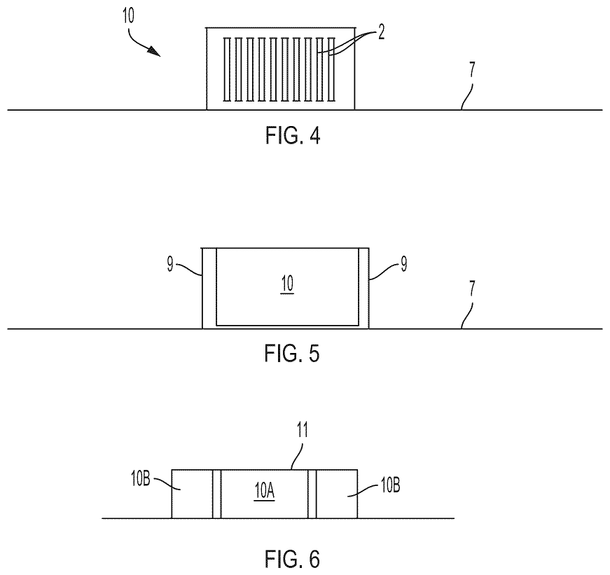

FIG. 4 illustrates a capacitor 10 with electrodes oriented vertically (e.g., perpendicularly) with respect to an underlying substrate 7 (e.g., printed circuit board, or PCB). The electrodes may have a cylindrical (e.g., barrel-wound) geometry or a rectangular (e.g., flat) geometry.

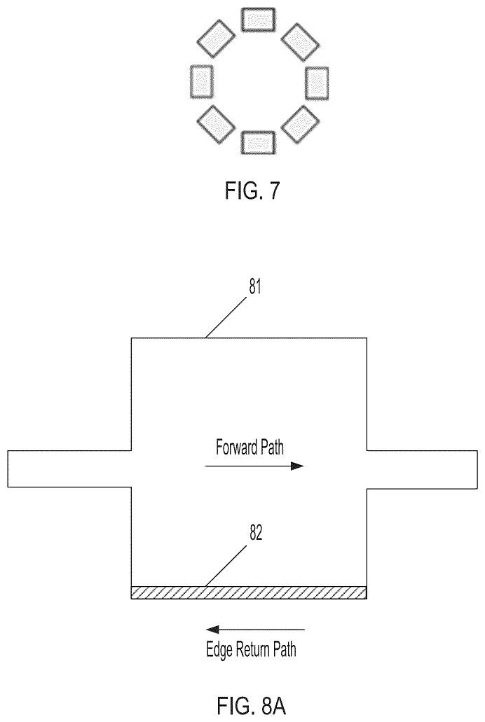

A connection to the top of a capacitor may be made by one or more leads. In some embodiments, lead(s) 9 may be positioned on the side of the capacitor and extending down from the top to the substrate or extending out from the side of the capacitor before extending down to the substrate, as shown in FIG. 5. The lead(s) 9 may be connected to a number of electrodes on top of the capacitor. In some cases, the lead(s) 9 may include a plurality of leads. In some cases, the lead(s) 9 may be a single lead that is continuous in the circumferential direction and extending around the exterior and top of the capacitor (e.g., as a cup-shaped conductor).

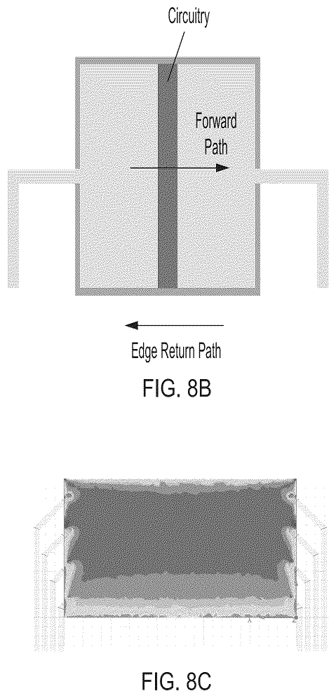

Another way of providing a current path to the top of the capacitor is to use another capacitor. That is, the lead(s) 9 of FIG. 5 may be replaced with one or more capacitors, which may also have vertically-oriented electrodes, as illustrated in FIG. 6, which shows a cross-sectional view. The capacitor 10A may have a disk shape in top-view. The return capacitor 10B may be a single capacitor having an annular shape. A shorting electrode 11 may connect the top terminals of capacitors 10A and 10B. Both the capacitor 10A and the return capacitor 10B may be film capacitors with barrel-wound electrodes and dielectric layers.

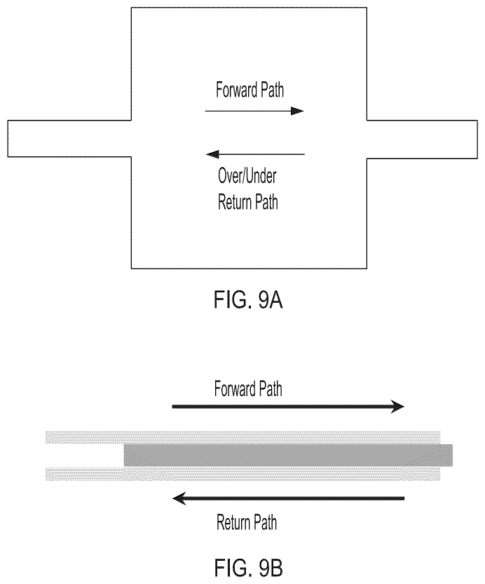

In some embodiments, barrel-wound electrodes may be replaced with parallel plate capacitors arranged in a circle and shorted at their tops. With respect to FIG. 6, capacitor 10A, capacitor 10B or both capacitors 10A and 10B may be replaced by a plurality of parallel-plate capacitors arranged in a circular geometry, as shown in FIG. 7, which shows a top-view. If both the capacitor 10A and 10B are arranged as shown in FIG. 7, there will be two concentric circles of parallel plate capacitors. As another example, the capacitor of FIG. 5 may be replaced by a plurality of parallel-plate capacitors arranged in a circular geometry, as shown in FIG. 7. In such an arrangement, the return lead 9 can come back down from the top of the capacitors to the substrate.

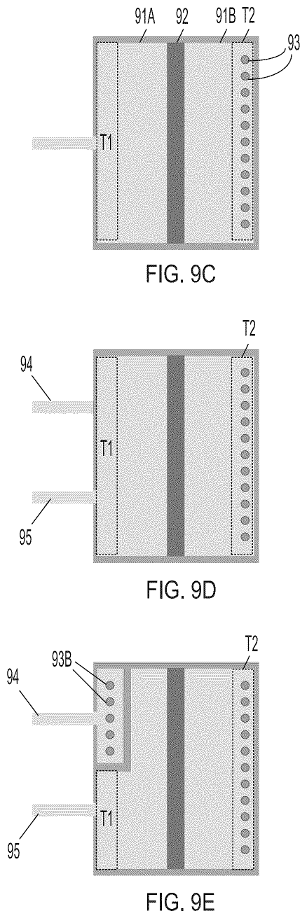

The inventors have recognized and appreciated that, in some applications, current may flow along a conductive sheet, and the positioning of the return current path may affect the losses caused by the proximity effect. The inventors have recognized and appreciated that if the return path for the alternating current path is brought around the edge of the conductive sheet, current crowds at the edge(s) of the sheet near the return current path due to the proximity effect, which increases loss, particularly at higher frequencies. This effect is illustrated in FIG. 8A, which shows a Forward Path for alternating current from left to right through a conductive sheet 81. If the return path is made with leads or other conductors around the bottom edge of the conductive sheet and roughly in-plane, the proximity effect produces relatively high losses 82 at the bottom edge of the sheet. For example, FIG. 8B shows an example of a printed circuit board (PCB) in which alternating current flows from left to right along a sheet of conductor, and through circuitry separating the left side of the conductive sheet from the right side of the conductive sheet. As illustrated in FIG. 8B, a return path for the conductors extends around the bottom edge. When the current loop is closed at the bottom edge, the proximity effect produces relatively high losses at the bottom edge of the sheet. This effect is also illustrated in the simulation illustrated in FIG. 8C, which shows a number of leads extending toward the bottom of the sheet, which produces relatively high losses at the bottom edge of the sheet.

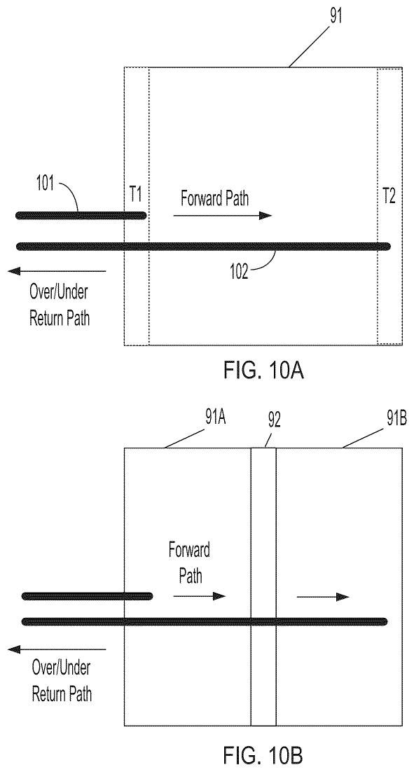

The inventors have recognized that bringing the return current path above or below the conductive sheet reduces current crowding and associated losses from the proximity effect. This is illustrated in FIG. 9A, which shows a plan view illustrating the return path flowing over and/or under the conductive sheet. FIG. 9B shows a cross-sectional view for an example in which the return path extends under the forward path. Alternatively or additionally, the return current path may extend over the forward current path.

FIG. 9C shows an example similar to FIG. 9B, in which the forward and return current paths are formed in conductive layers of a PCB. Alternating current flows from terminal T1 across the conductive sheet portion 91A, through circuitry 92, and across conductive sheet portion 91B to terminal T2. The circuitry 92 may be any circuitry, including but not limited to one or more capacitors, power converters, inverters, rectifiers, or power switches, for example. Conductive vias 93 at the right side of FIG. 9C allow the current to flow to a conductive layer below (and/or above) the layer in which the forward current flows. A side view of an example with the return current flowing in a conductor below the conductive sheet portions 91A and 91B is shown in FIG. 9B. At the left side of FIG. 9C, the return current lead or trace may be below the forward current lead or trace. FIG. 9D shows an example similar to that of FIG. 9C, in which the return lead or trace at the left side is not under the forward current lead or trace. FIG. 9E shows an example similar to that of FIG. 9D, in which a second set of vias are present at the left side to bring the return current path back up (and/or down) to the same layer in which the forward current flows, so that both the forward and return current lead or traces may extend from the same layer, which may simplify manufacturing.

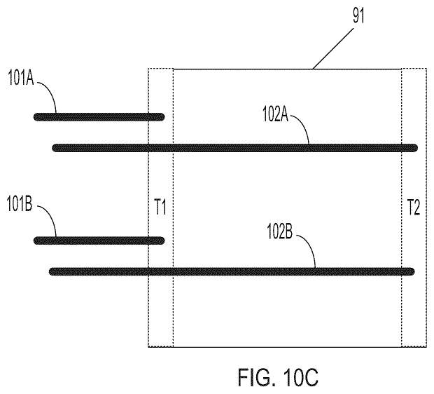

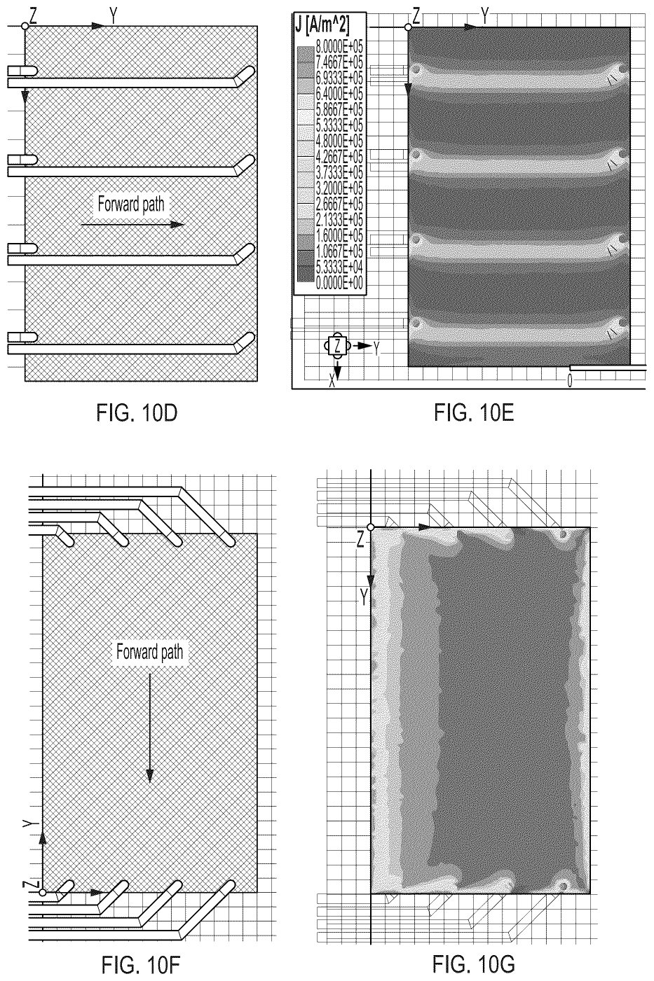

In some embodiments, a return current path for the current may be provided by one or more conductors, including, but not limited to wires or conductive foil layers. FIG. 10A shows in example in which a first wire 101 is attached to the first terminal T1 of the conductive sheet 91 to provide a forward path for alternating current, and a second wire 102 is attached to the second terminal T2 of the conductive sheet 91 to provide a return path for alternating current. The second wire 102 may be positioned above or below the conductive sheet 91 to limit losses caused by the proximity effect. In the example of FIG. 10A, the second wire 102 is positioned above the conductive sheet. In some embodiments, the first and/or second wires 101, 102 may be litz wire. However, the techniques described herein are not limited to the wires being litz wire. The wires 101 and 102 may be attached to the conductive sheet using any suitable technique, such as soldering and/or with ring and screw terminals, for example. FIG. 10B shows another example in which the conductive sheet 91 includes two conductive sheet portions 91A, 91B separated by circuitry 92. As in the examples mentioned above, the circuitry 92 may be in series with the forward current path.

The inventors have recognized and appreciated that making connections to the terminals T1 and/or T2 at distributed locations by a plurality of wires connected in parallel helps to spread out the current distribution and reduce losses. FIG. 10C shows an example in which two wires 101A and 101B connected in parallel connect to the terminal T1 at two locations spaced apart from one another. Similarly, two wires 102A and 102B connected in parallel connect to the terminal T2 at two locations spaced apart from one another. However, the number of wires connected in parallel is not limited to two. The more wires are connected in parallel and connected at distributed locations on the conductive sheet, the less current crowding occurs, leading to lower losses. As mentioned above, the wires for the return current may extend above and/or below the conductive sheet to avoid current crowding at the edges of the conductive sheet. FIG. 10D shows an example in which the return current path is provided by four wires connected in parallel and attached at distributed locations on the right side of the conductive sheet. FIG. 10E shows a simulation corresponding to FIG. 10D illustrating minimal current crowding occurs in the conductive sheet, near the return current wires. For comparison, FIG. 10F shows an example in which the leads extend around an edge of the conductive sheet. FIG. 10G shows the configuration of 10F results in significant current crowding at the left side of the sheet. The configuration of FIG. 10D shows a significant improvement in equivalent series resistance (ESR), resulting an ESR of 0.24 milliohms, compared to an ESR of 0.95 milliohms for the configuration of FIG. 10F.

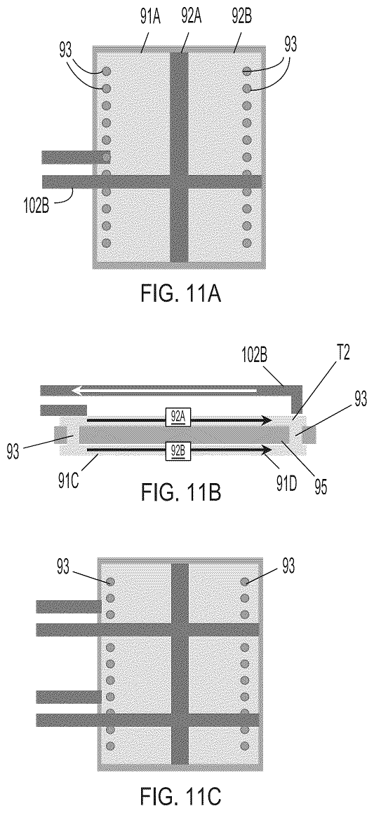

In some embodiments, a substrate, such as a PCB, may provide parallel current paths in a plurality of conductive layers. For example, a PCB may provide a plurality of forward current paths, as shown in the examples illustrated in FIGS. 11A-11C. FIG. 11A illustrates a top view of an embodiment similar to that of FIG. 10A, with a wire 102B for the return current path extending over the conductive sheet portions 91A, 91B, and a plurality of vias 93 extending down from the conductive sheet portions 91A, 91B to second conductors 91C, 91D in a second layer of the substrate, as shown the side view of FIG. 11B. The second conductor 91C, 91D may also be one or more conductive sheets. In the example of FIGS. 11A and 11B, first circuitry 92A is connected in the top forward current path, and second circuitry 92B is on the bottom side of the PCB, connected in the bottom forward current path. FIG. 11B illustrates the top and bottom conductor layers of the substrate are separated by an insulating layer 95 of the PCB along a portion of their length, but are connected in parallel by the vias 93. A wire 102B for the return path is connected to the terminal T2. FIG. 11C shows top view of an embodiment similar to that of FIGS. 11A and 11B, but with a plurality of wires connected to each terminal at different locations to avoid current crowding, as in the embodiment of FIG. 10C.

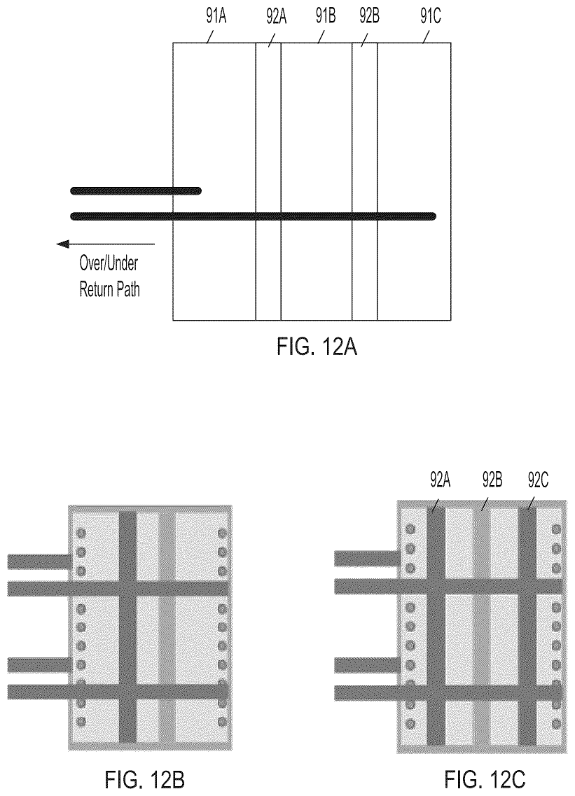

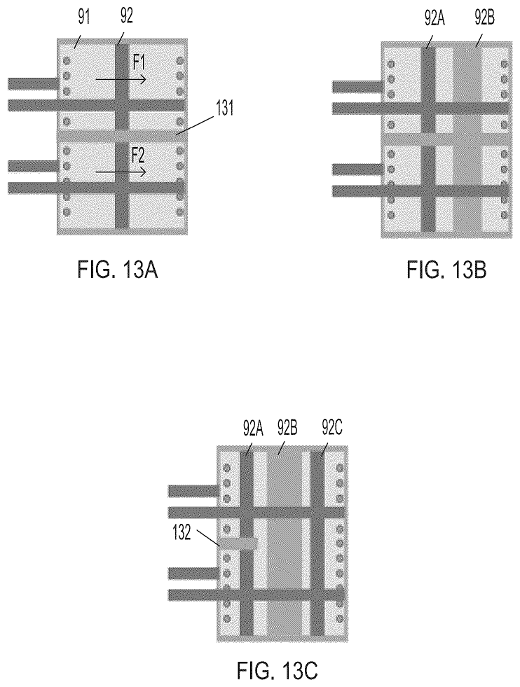

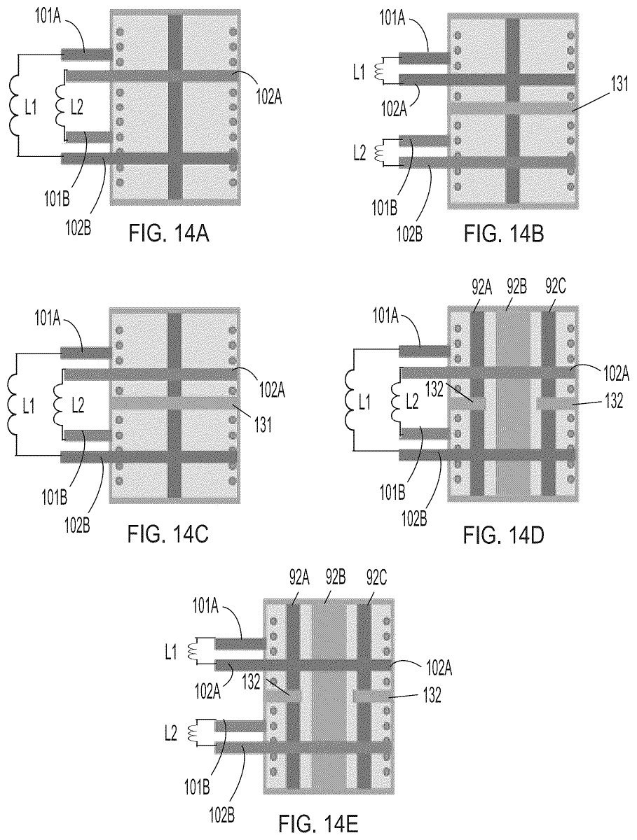

In some embodiments, there may be a plurality of columns or banks of circuitry connected to and separating respective portions of a conductive sheet. FIG. 12A illustrates an example in which circuitry 92A is connected between respective portions 91A and 91B of a conductive sheet, and circuitry 92B is connected between respective portions 91B and 91C of the conductive sheet. The circuitry 92A and 92B may be the same type of circuitry or different types of circuitry, examples of which are described above. FIG. 12B shows how this concept can be combined with the concept of distributed connections (e.g., parallel connections) to different locations along terminals of a conductive sheet (illustrated in FIG. 10C). FIG. 12C illustrates this may be extended to three (or more) columns or banks of circuitry 92A, 92B, and 92C, which may be same types of circuitry as one another or different from one another. Although FIG. 12B and FIG. 12C illustrate vias for the use of parallel forward conductive paths (as illustrated in FIGS. 11B and 11C), the vias and second layer of conductors is optional in these examples and in the examples shown in FIGS. 13A-14E. It should be appreciated that there may be any number of columns or banks of circuitry, not limited to three.

In some embodiments, a conductive sheet may have completely or partially separate forward current paths or return current paths. FIG. 13A illustrates an example similar to that of FIG. 11C with an insulating region 131 free of conductor separating the top portion the conductive sheet 91 from the bottom of the conductive sheet 91, which separates the current paths F1 and F2 in the top and bottom portions of the conductive sheet. Such a technique may be useful where separate current paths are needed, such to provide separate circuit components for separate conductive paths F1 and F2. For example, if the top and bottom portions of the conductive sheet 91 are connected to different coils, the circuitry 92 connected between respective portions of the conductive sheet may operate separately on each path. For example, if the circuitry 92 includes capacitors, the circuitry 92 may provide separate capacitance in each conductive path, which may be useful for equalizing current in each path (capacitive ballasting). As another example, the circuitry 92 may include a rectifier, inverter, or switches of a rectifier or inverter for processing the current through each path. In some cases, a plurality of columns or banks of circuitry may be included, as shown in FIG. 13B. FIG. 13B shows circuitry 92A and 92B, which may be the same or different types of circuitry. In some cases, the forward paths F1 and F2 may be partially separated from one another rather than completely separated from one another. FIG. 13C shows the insulating region 131 may extend across only a portion of the conductive sheet, which produces separate current paths to the left of the circuitry 92A and a combined current path to the right of circuitry 92A. It should be appreciated that any number of insulating regions 131 or 132 may be included to provide any number of partially separate or completely separate current paths.

In some embodiments, a conductive sheet may be connected to a plurality of coils or other electromagnetic components, including but not limited to wireless power transfer coils or inductive elements (e.g., inductors). FIGS. 14A-14E show the coils may be connected to the conductive sheet in a variety of configurations. FIG. 14A shows a first coil L1 may be connected between conductor 101A conductor 102B, and a second coil L2 may be connected between conductor 102A and conductor 101B. FIG. 14B illustrates another example with separate current paths provided by insulating region 131. In the example of FIG. 14B, coil L1 is connected between conductors 101A and 102A. Coil L2 is connected between conductors 101B and 102B. FIG. 14C illustrates an example with the coils connected in a similar manner to that shown in FIG. 14A, but with the addition of insulating region 131 to provide separate current paths. FIG. 14D shows an example with coils L1 and L2 connected similarly to the example of FIG. 14A, with the inclusion of circuitry 92A, 92B and 92C and insulating regions 132 partially insulating the current paths, such that the portions of the current paths through circuitry 92A and 92C are separate, and the current paths are combined when passing through circuitry 92B. FIG. 14E shows an example in which the coils L1 and L2 are connected similarly to the example of FIG. 14B, but with the inclusion of circuitry 92A, 92B and 92C and insulating regions 132 partially insulating the current paths, as in FIG. 14D.

The electrodes, leads and other conductors described herein may be, wholly or partially, made of any electrically conductive material or combination of materials, including but not limited to one or more metals such as silver, copper, aluminum, gold and titanium, and non-metallic materials such as graphite. The electrically conductive material may have an electrical conductivity of higher than 200 kS/m, optionally higher than 1 MS/m.

The magnetic cores described herein may be, wholly or partially, made of one or more ferromagnetic materials, which have a relative permeability greater than 1, optionally greater than 10. The ferromagnetic materials may include, but are not limited to, one or more of iron, various steel alloys, cobalt, ferrites including manganese-zinc (MnZn) and/or nickel-zinc (NiZn) ferrites, nano-granular materials such as Co—Zr—O, and powdered core materials made of powders of ferromagnetic materials mixed with organic or inorganic binders. However, the techniques and devices described herein are not limited as to the particular material of the magnetic core.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “forward” and “return” in relation to current paths are used herein as labels to differentiate current paths, and do not imply or require any particular magnitude or direction of current flow. For example, positive or negative current may flow through the forward path and positive or negative current may flow through the return path.

The terms “substantially,” “approximately,” “about” and the like refer to a parameter being within 25%, optionally within 10%, optionally less than 5% of its stated value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An apparatus, comprising:
at least one conductive sheet forming a forward current path from a first terminal of the at least one conductive sheet to a second terminal of the at least one conductive sheet, the at least one conductive sheet having a top, a bottom, and at least one edge; and
at least one conductor forming a return current path from the second terminal, the at least one conductor extending over the top of the at least one conductive sheet or below the bottom of the at least one conductive sheet.

2. The apparatus of claim 1, further comprising circuitry connected between the first terminal and the second terminal.

3. The apparatus of claim 2, wherein the circuitry is connected between a first portion of the at least one conductive sheet and a second portion of the at least one conductive sheet.

4. The apparatus of claim 2, wherein the circuitry comprises at least one capacitor.

5. The apparatus of claim 2, wherein the circuitry comprises at least one switch.

6. The apparatus of claim 2, wherein the circuitry comprises a rectifier or an inverter.

7. The apparatus of claim 2, further comprising second circuitry connected between the first terminal and the second terminal.

8. The apparatus of claim 1, further comprising an insulating region at least partially separating respective current paths in the at least one conductive sheet.

9. The apparatus of claim 8, wherein the insulating region fully insulates the respective current paths.

10. The apparatus of claim 7, wherein the second circuitry is of a same type as the circuitry or of a different type.

11. The apparatus of claim 1, wherein the at least one conductive sheet is formed in a conductive layer of a printed circuit board.

12. The apparatus of claim 11, wherein the at least one conductor comprises a second conductive layer of the printed circuit board.

13. The apparatus of claim 12, wherein the at least one conductor comprises one or more vias connecting the at least one conductive sheet and the second conductive layer.

14. The apparatus of claim 13, wherein the at least one conductor further comprises one or more second vias extending from the second conductive layer to the at least one conductive sheet.

15. The apparatus of claim 1, wherein the at least one conductor comprises a plurality of conductors connected in parallel and connected to the second terminal at different locations.

16. The apparatus of claim 1, wherein the at least one conductor comprises litz wire or a foil conductor.

17. The apparatus of claim 1, wherein the at least one conductive sheet is electrically connected to a coil.

18. The apparatus of claim 1, wherein the at least one conductor forms a lead of a coil.

19. The apparatus of claim 17, wherein the coil is a wireless power transfer coil or inductive component.

20. The apparatus of claim 17, wherein the at least one conductive sheet is electrically connected to a second coil.

21.-34. (canceled)
